(19) United States
(12) Patent Application Publication
(10) Pub. No.: US 2008/0073114 A1
(43) Pub. Date: Mar. 27, 2008

(54) TECHNIQUE FOR PLATING SUBSTRATE DEVICES USING VOLTAGE SWITCHABLE DIELECTRIC MATERIAL AND LIGHT ASSISTANCE

(76) Inventors: Lex Kosowsky, San Jose, CA (US); Robert Fleming, San Jose, CA (US)

Correspondence Address: SHEMWELL MAHAMEDI LLP, 4880 STEVENS CREEK BOULEVARD, SUITE 201, SAN JOSE, CA, 95129, US

(21) Appl. No.: 11/860,522

(22) Filed: Sep. 24, 2007

Related U.S. Application Data
(60) Provisional application No. 60/826,746, filed on Sep. 24, 2006.

(51) Int. Cl. H05K 1/11; C25B 9/00; C25D 5/48; G06F 19/00; H01L 21/428

(52) U.S. Cl. 174/262; 204/274; 205/221; 205/91; 438/795; 700/121; 257/E21.475

(57) ABSTRACT

An electroplating process is performed using a substrate that includes a thickness of voltage switchable dielectric (VSD) material having photoactive components that are dispersed, mixed or dissolved in a binder of the VSD material. A pattern of conductive elements may be formed on the substrate by switching the VSD material from a dielectric state to a conductive state using, in part, voltage generated by directing light onto the thickness and VSD material.

### RELATED APPLICATIONS

This application claims benefit of priority to Provisional U.S. Patent Application No. 60/826,746, filed Sep. 24, 2006, entitled VOLTAGE SWITCHABLE DEVICE AND DIELECTRIC MATERIAL WITH HIGH CURRENT CARRYING CAPACITY AND A PROCESS FOR ELECTROPLATING THE SAME; the aforementioned priority application being hereby incorporated by reference in its entirety.

### BACKGROUND

Current carrying structures are generally developed using a process in which a substrate is subjected to a series of manufacturing steps. Examples of such current carrying structures include printed circuit boards, printed wiring boards, integrated circuit (IC) chip package substrates, backplanes, and other micro-electronic types of circuitry.

The manufacturing steps are typically performed on a substrate made of rigid, insulative material such as epoxy-impregnated glass fiber laminate or flexible film such as polyimide. Conductive material such as copper is formed according to a pattern defining conductors, including ground and power planes.

Some previous current carrying devices are manufactured by layering a conductive material over a substrate. A mask layer is then deposited on the conductive layer. The mask layer is exposed and developed. The resulting pattern determines select regions where conductive material is to be removed from the substrate. The conductive layer is removed from the select regions by etching. The mask layer is subsequently removed, providing a patterned layer of conductive material on a surface of the substrate.

In some processes, a seed layer may be formed through vacuum metal deposition. In other known processes, an electroless process is used to deposit conductive lines and pads on the substrate. A plating solution is applied to enable conductive material to adhere to the substrate on selected portions of the substrate to form patterns of conductive lines and pads.

To maximize available circuitry in a limited footprint, substrate devices sometimes employ multiple substrates, or use both surfaces of one substrate to include componentry and circuitry. The result in either case is that multiple substrate surfaces in one device need to be interconnected to establish electrical communication between components on different substrate surfaces.

Previous devices develop sleeves or vias that extend through the substrate. In multi-substrate devices, vias extend through at least one substrate to interconnect one surface of that substrate to a surface of another substrate. The sleeves or vias are provided with conductive layering to establish an electrical connection between the substrate sides being interconnected. In this way, an electrical link is established between electrical components and circuitry on two surfaces of the same substrate, or on surfaces of different substrates.

With previous devices, vias can be plated by seeding surfaces with conductive materials. During an electrolytic process, the surfaces of the vias are plated by bonds formed between the seeded particles and the plating material.

In other devices, via can be provided with a layer of conductive material using adhesives. In these devices, the bond between the vias and conductive material is mechanical in nature.

Certain materials, referred to below as voltage switchable dielectric material, have been used in previous devices to provide over-voltage protection. Electrical resistance properties of such materials regulate voltage surges from, for example, lightning, static discharge, or power surges. Voltage switchable dielectric material are included in some devices, such as printed circuit boards. In these devices, voltage switchable dielectric material is inserted between conductive elements and the substrate to provide over-voltage protection.

U.S. Pat. No. 6,797,145 (hereby incorporated by reference in its entirety) describes a technique for implementing VSD material within a current carrying structure in a manner that enables the VSD material to be used to plate the conductive element. Such plating techniques may also enable the device to have some capabilities for handling ESD events.

### BRIEF DESCRIPTION OF THE DRAWINGS

FIG. 1A-FIG. 1G illustrate an electroplating process using photoactive VSD material, according to an embodiment of the invention.

FIG. 2A-FIG. 2G illustrate a variation to the electroplating process described with an embodiment of FIG. 1A-FIG. 1G, under another embodiment of the invention.

FIG. 3A-FIG. 3D illustrates use of highly-focused light directed onto select portions of a VSD layer in accordance with a pre-determined pattern, according to one or more embodiments.

FIG. 4 illustrates a system for implementing the application of focused light onto a layer of VSD material, for purpose of enabling the formation of a pattern of conductive elements to be formed thereon during an electrolytic (or metal deposition) process, under an embodiment of the invention.

FIG. 5 illustrates an embodiment that utilizes a combination of light and VSD material on a substrate undergoing an electrolytic process in order to form one or more conductive vias, according to an embodiment of the invention.

FIG. 6 illustrates a section of a substrate that undergoes multiple electroplating or metal deposition processes, including an initial process that uses an underlying layer of VSD material, under an embodiment of the invention.

FIG. 7 illustrates a control system for use with one or more embodiments described herein.

### DETAILED DESCRIPTION

Embodiments described herein provide for electroplating substrates to have electrical components and traces using photoactive voltage switchable dielectric (VSD) material. In particular, embodiments provide for depositing a layer of photoactive VSD material and then performing an electroplating process by switching the VSD material into a conductive state using a combination of light and applied voltage.

According to an embodiment, a layer of VSD material is provided on a surface of a substrate, device or component that is being plated or undergoing an electroplating or metal process. The VSD material that comprises the layer is capable of being switched from a dielectric state into a conductive state with application of energy that exceeds a threshold level. In particular, a voltage in excess of a threshold level may be applied to the layer of VSD material in order to switch the VSD material into the conductive state. One or more embodiments provide that the VSD material includes photoactive particles or components, dispersed, mixed or dissolved, in a matrix or binder composition, that respond to light by generating electron/hole pairs. By the generation of electron hole/pairs, the activation energy can be lowered for using electrons to reduce the metal+ions (e.g. Cu⁺²) in the plating solution to the metal. Such particles may be dispersed in the VSD material (e.g. as part of a polymer binder) so that light may be applied to the VSD material to reduce the threshold voltage level needed to switch the VSD material into a conductive state. Once in the conductive state, exposed portions of the layer of VSD material may be used to bond with conductive elements that are contained in the solution or medium that is applied to the surface on which the VSD material is provided.

Among other benefits, some embodiments described herein enable an electroplating technique that eliminates one or more steps that are otherwise performed in a conventional electroplating process. Additionally, the use of a layer of VSD material facilitates the integration of VSD material as a protective feature that protects components of the substrate from electrostatic discharge (ESD) and other electrical events. Embodiments such as described herein may be used to plate printed circuit board (PCBs), display devices and backplanes, integrated circuit devices and packages, semiconductor components and devices, and other substrate devices. Embodiments may also be used to form conductive materials on flexible substrates, such as those formed from polyimide. Still further, embodiments may provide conductive or current-carrying elements or formations on devices or portions thereof, including on integrated portions of housings and thicknesses of finished devices or components, such as handheld electronic devices and modularized packages for use in devices.

VSD material generally refers to material that exhibits the property of (i) acting as a dielectric in the absence of some threshold voltage or energy, (ii) becomes conductive when applied a voltage or energy that is in excess of a threshold voltage/energy level. The threshold voltage/energy level may vary for different kinds of VSD materials, but it generally exceeds normal operational voltages of electrical devices. For example, in the application of plating, the threshold voltage level for VSD material may be in exceed of 50 volts, and of the range of 50-1000 volts or more. As a result of this switching property, VSD material is often used to provide transient electrical connections that can protect against transient electrical events, most notably electrostatic discharge (ESD).

Moreover, according to one or more embodiments, VSD material has a characteristic of being uniform in its composition, while exhibiting electrical characteristics as stated. In such an embodiment, the VSD material is comprised of a matrix or binder that contains conductive and/or semi-conductive material that is substantially uniformly distributed.

According to an embodiment, an electroplating process is performed using a substrate that includes a thickness of VSD material having photoactive particles. A pattern of conductive elements may be formed on the substrate by switching the VSD material from a dielectric state to a conductive state using, in part, voltage generated by directing light onto the thickness and VSD material.

In another embodiment, a thickness comprising a layer of VSD material is immersed in or otherwise subjected to a medium containing conductive particles. The layer of VSD material includes photoactive particles and is triggerable to switch from a dielectric state into a conductive state with application of energy that exceeds a designated threshold level. Focused light may be directed onto the layer of VSD material in accordance with a designated pattern. The focused light may cause select portions of the VSD material that are identified in the designated pattern to trigger into the conductive state, so that conductive particles in the medium bond to the VSD material in accordance with the designated pattern.

Still further, an embodiment includes a system for electroplating a substrate provided in a medium of conductive particles. The system may include a light emitter and logic to control the light emitter. The light emitter may direct a beam of focused light onto the substrate. Logic may be coupled to or provided with the light emitter that is configured to control a position where the beam is provided. Additionally, the logic may be configured to position the beam generated from the light emitter on a layer of a VSD material provided on the substrate using pattern data that defines a desired pattern of a conductive layer that is to be formed on the substrate. The VSD material may include photoactive particles and may also be triggerable to switch from a dielectric state into a conductive state with application of energy that exceeds a designated threshold level. The light emitter may be configured to direct the beam to provide sufficient energy to select regions of the layer of VSD material that exceeds the designated threshold of energy of the VSD material at those select regions, so as to cause the VSD material at the select regions to switch from the dielectric state into the conductive state.

Still further, another embodiment provides for a control system for controlling a manufacturing process for a substrate device. The control system may include one or more processing resources that communicate data to the manufacturing process. The data may include instructions or parameters to direct the manufacturing process to perform steps that include (i) providing a substrate that includes voltage switchable dielectric (VSD) material formed with photoactive particles; and (ii) forming a pattern of current-carrying elements by switching the VSD material from a dielectric state to a conductive state using, in part, voltage generated by directing light on the substrate and VSD material.

Photoactive VSD Material

Embodiments described herein provide for a electroplating technique that incorporates the use of VSD material, and more specifically, light-receptive VSD material. Examples of VSD material for use with embodiments described herein are provided in U.S. patent application Ser. No. 11/881,896 and U.S. patent application Ser. No. 11/829,951, both of which are incorporated by reference in their respective entirety. As mentioned, light-receptive VSD material has a composition comprising a binder and dispersed particles that are photoreceptive. In particular, the particles generate electron/hole pairs when they absorb light.

According to an embodiment, the VSD material may be formed from a binder that includes dispersed fullerenes. Fullerenes are known as good electron acceptors, and this property is exploited in the development of organic photovoltaic devices. In a typical organic photovoltaic device, fullerenes are dispersed into a polythiophene and coated between a transparent anode and a cathode. When cast, light is absorbed by the polythiophene generating an electron/hole or exciton, and the exciton diffuses to the polymer-fullerene interface and the fullerene accepts the electron, thus splitting the electron/hole pair. Embodiments described herein exploit this property for electroplating by blending a light absorbing particle or material (such as a fullerenes or titanium dioxide) into a dielectric polymer to produce a light-receptive VSD material (optionally metal or semiconductive particles may be added). Examples of light absorbing materials include pentacenes, perylenes, polythiophene/fullerenes, and known photoactive polymers and materials such as copper indium gallium deselenide (CIGS) and silicon particles. As described with embodiments provided below, during electroplating, the VSD material may be pulsed with a certain voltage and current and also simultaneously pulsed with light to increase conduction of the substrate surface for more efficient electroplating. Organic semiconductors may also be used to increase the efficiency by which light is absorbed, excitons are generated, and electrons and holes are transported. Examples of organic semiconductors are, but not limited to: polythiophenes, poly(3,4-ethylenedioxythiophene)/poly(styrene sulfonate) (PEDOT/PSS), oligothiophenes, polyarylamines, polyphenylene vinylenes, polyvinylnaphthalene, polysilanes, and polyanilines. Organic semiconductive molecules may be functionalized to react with the binder material, for example, carbezole or naphthalene may be functionalized with amine(s) to react with the epoxy matrix.

Numerous other examples of photoactive particles and materials exist for including in a binder of matrix of VSD material, for purpose of enabling the VSD material to be photoactive or otherwise light responsive. In one embodiment, titanium dioxide particles are dispersed as photoactive particles in the binder of the VSD material. Alternative variations may use, for example, zinc oxide or cerium oxide as photoactive particles, as either a substitute for addition to other particles or materials that are photoactive (e.g. such as fullerenes or titanium dioxide).

Embodiments described herein provide for use of light-receptive VSD material as part of an electroplating process. For example, fullerenes or other photo-receptive particles may be dispersed uniformly in a binder or matrix. The substrate 110 may be planar or non-planar.

Voltage Addition from Light Application

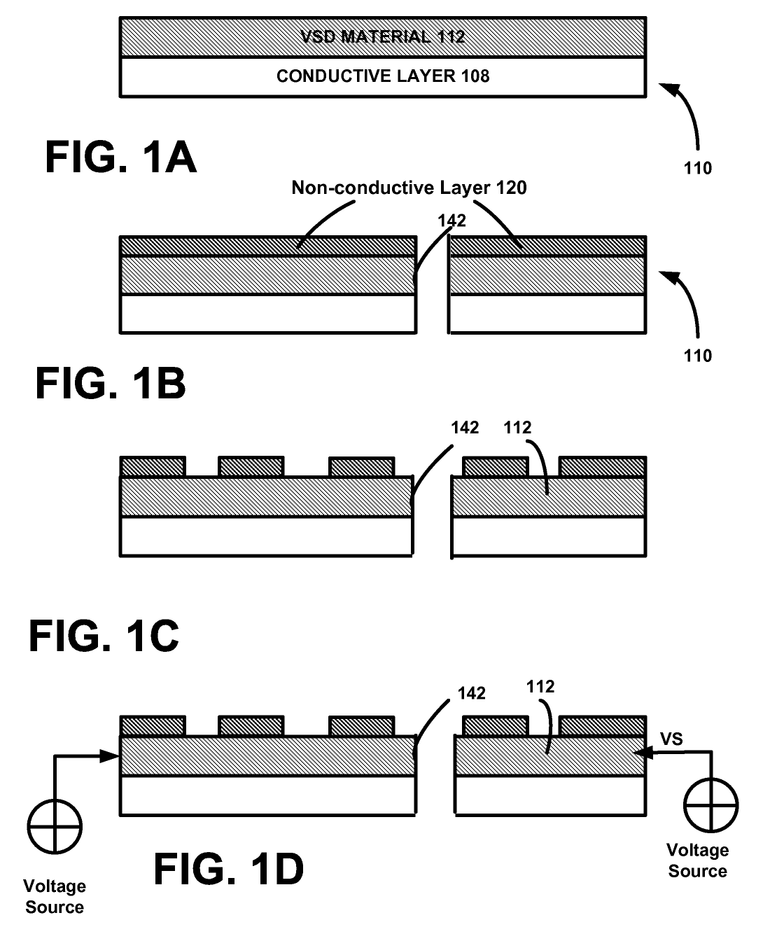

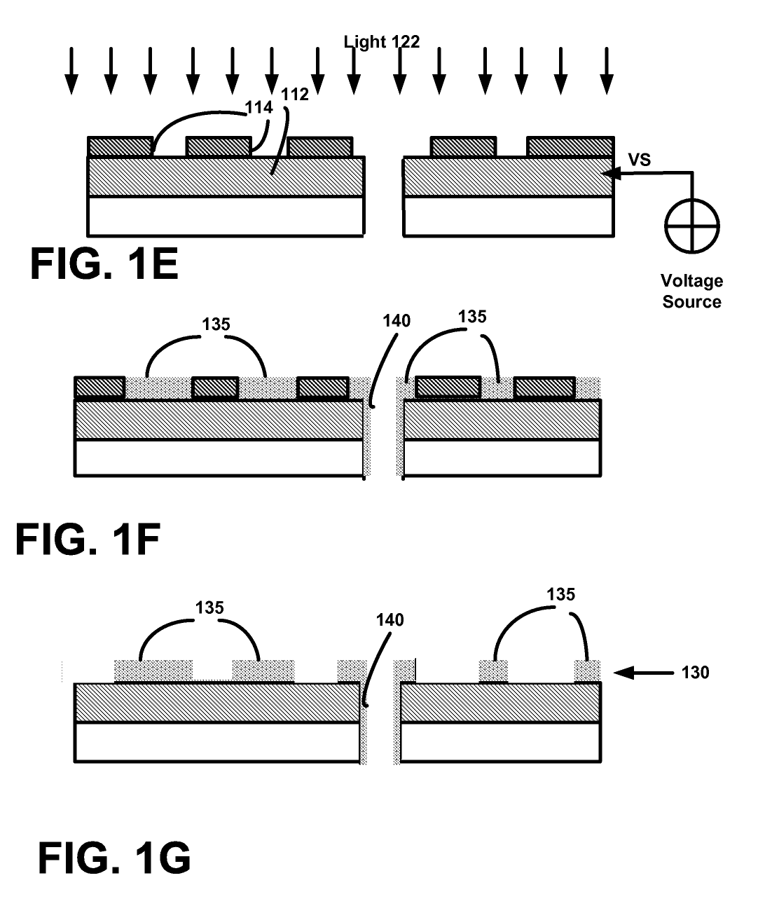

FIG. 1A-FIG. 1G illustrate an electroplating process using photoactive VSD material, according to an embodiment of the invention. In particular, an embodiment such as described with FIG. 1A-FIG. 1G provides for forming electrical elements or components over a layer of VSD material that is provided on a substrate or other thickness of an electrical device or component under manufacture.

A process such as described by an embodiment of FIG. 1A-FIG. 1G illustrates a process in which electrical properties of a VSD material are used to develop conductive (or current-carrying) material in accordance with a predetermined pattern. In particular, an embodiment of FIG. 1A-FIG. 1G provides for the use of light to provide an additive component of energy that causes a layer of VSD material to switch into a conductive state. In the conductive state, the VSD material is able to receive conductive mass deposited from an electrolytic or metal-deposition process.

In FIG. 1A, VSD material 112 is selected and provided as a layer over a conductive layer 108 to form a substrate 110 or other thickness for electroplating. The conductive layer 108 may be provided as, for example, a plate grid or wire-mesh. Other embodiments may omit the conductive layer 108, or provide for it to be non-conductive (such as a backing). As mentioned with other embodiments, the selected composition may be photoactive, such as by way of including photoactive particles. In addition to being photoactive, an embodiment provides that the VSD material 112 may be selected or configured to have specific electrical properties. The properties include a characteristic measurement of energy that, when applied to a known quantity of the VSD material, causes the VSD material to switch from a dielectric state into a conductive state. In some applications, the characteristic measurement may be made in the form of a known, experimentally derived threshold or characteristic voltage that, when applied to the layer of VSD material in a particular environment, causes some or all of the layer of VSD material to switch into the conductive state. Embodiments described herein recognize that for purpose of electroplating, only a surface depth of the overall VSD layer needs to be made conductive. As will be described, the substrate and/or layer of VSD material 112 may be applied a voltage that is less than the threshold voltage level that is expected to make some or all of the VSD material conductive when subjected to an electrolytic process. Additionally, the substrate 110 comprising the VSD layer 112 may be formed in accordance with dimensions, shape, composition and properties for a particular application (e.g. type of substrate device).

Other electrical properties that may be considered when the VSD material is selected or configured include leakage current (or off-state resistance), as determined by integration of the VSD material in the completed and operational form of the device or component that is under manufacture with the process being described. In particular, embodiments provide that once the VSD material 112 is used in the electroplating process, the layer of VSD material 112 remains on the device/component under formation or manufacture for the lifetime of that device or component. The inherent properties of the VSD material may enable the VSD material to protect electrical elements and components provided on or with the device or component from ESD and other electrical events. For this reason, the operating conditions of the components and elements of the substrate device may be required to tolerate leakage current that may result from inclusion of a VSD material layer of a particular type.

FIG. 1B a non-conductive layer 120 is deposited over the combined substrate. The non-conductive layer 120 may be formed from, for example, a photoimageable material, such as a photoresist layer. In one implementation, the non-conductive layer 120 is formed from a dry film resist.

In FIG. 1C, the non-conductive layer 120 is patterned on the combined substrate 110. In an embodiment, a mask is applied over the non-conductive layer 120. The mask may be used to expose portions of the VSD material 112 through the positive photoresist. The pattern of the exposed regions of the VSD material 112 on the substrate 110 may correspond to a pattern in which current carrying elements will be subsequently formed on the substrate.

The selected composition for VSD material may have an associated characteristic threshold voltage level that can be experimentally determined for the particular composition when applied as a layer of given thickness to a substrate or other surface undergoing an electrolytic process. The threshold voltage level may correspond to the voltage level that is known to make the entire thickness, or significant portions thereof, conductive when, for example, it is submerged in an electrolytic bath. This voltage level may be referenced as the threshold voltage level VT. In the process step of FIG. 1D, a voltage VS is applied to the VSD material. The voltage VS may be applied to be just under the threshold voltage VT, so as to not switch any portion of the layer of VSD material on when applied:

VT>VS (1)

Thus, the application of the voltage VS in and of itself does not cause the VSD material to switch into the conductive state.

As mentioned, the VSD material includes a photoactive composition. In the step of FIG. 1E, light 122 is cast or otherwise directed onto the combined substrate while the applied voltage VS is present. The energy resulting from the photoactive VSD material is generated at the surface of the layer of VSD material 112. The thickness of the VSD material affected may only measure, for example, angstroms or nanometers in thickness. The thickness of VSD affected by the directed light 122 may be referred to as the “surface thickness”. The result of the energy applied from the light to the exposed surface thickness is a decrease in the threshold voltage level. For a given quantity of VSD material in the exposed surface thickness (i), the threshold voltage needed to switch that quantity on in the presence of energy applied by the light 122 (VT(i)) may be such that:

VT(i)<VS<VT (2)

In other words, an embodiment provides that application of light 122 serves to switch incremental portions of the surface of the layer of VSD material-on. Different compositions of VSD material may be identified by the same or different unit (or normalized) surface quantities of VSD material, taking into account dimensions of area and thickness affected, and/or the type and power of light used.

Thus, the casting or directing of the light 122 onto the substrate switches select surface thickness portions of the VSD material from the dielectric state into the conductive state, and the select surface portions may match a desired pattern for a conductive layer that is to be formed on the substrate as a whole.

FIG. 1E and FIG. 1F show that the combined substrate 110 is subjected to an electrolytic process while light 122 is cast onto the combined substrate 110, so that the select surface portions of the VSD material is in a conductive state for at least part of the duration in which the electrolytic or metal deposition process takes place. The electrolytic process may correspond to immersing the substrate 110 in a solution and then generating the necessary voltage (using the cast light 122 and applied voltage) to switch the select surface portions of the layer of VSD material into the conductive state.

The directed light 122 may originate from anyone of many sources. For example, the light may be provided by a high-energy lamp, or alternatively through use of laser. Depending in part on the power of light 122, and the type of VSD material in use, the light 122 may enable the applied voltage VS to be between 10-50% of the threshold voltage level that would otherwise be required to switch the entire thickness of VSD material on in the absence of additional energy from light.

With embodiments such as described, embodiments facilitate creation of a conductive layer that is triggered by the pulsing of light. Light pulses enable control of a given duration that electroplating is performed. Furthermore, use of light 122 to switch selection select surface portions of the layer of VSD material on is relatively easier to accomplish that using applied voltage that is applied to an entire thickness.

The electrolytic process may be used to form a layer 130 that includes current carrying or conductive elements 135 deposited between formations of the patterned non-conductive layer 120. In an embodiment, an electroplating process deposits conductive elements on the substrate 110 in gaps 114 exposed by masking and removing the photoresist. Thus, the photoresist can be used to form the pattern of the conductive layer 130 in a subsequent electrolytic process.

Embodiments recognize that the layer of VSD material 112 may only be relevant for forming a seed layer where the current carrying elements 135 are formed. Specifically, once conductive elements are bonded to selected surface regions of the VSD material 112 (as dictated by the pattern), the bonded conductive elements provide the conductive surface on which other conductive elements from the electrolytic medium are bonded to. As such, one or more embodiments provide that the VSD material is switched into the conductive state for only a duration of time needed to form a seed layer. The electroplating process may then be continued without regard for the VSD material being conductive. As another variation, another electroplating process may be performed altogether without need for switching the VSD material into the conductive state.

Among other benefits, one or more embodiments enable an electroplating process to be performed on a surface without the need for forming a seed layer through a separate or independent process. For example, many conventional approaches use a separate vacuum metal deposition process to deposit a seed layer on a surface that is undergoing electroplating. In contrast to such conventional approaches, embodiments described with FIG. 1A-FIG. 1G and elsewhere in this application enable one or more electroplating processes to provide both the seed layer and subsequent plated thicknesses that form the conductive elements on the substrate or surface.

In FIG. 1G, the non-conductive layer 120 is removed as necessary from the substrate 110. In an embodiment in which the non-conductive layer 120 is the photoresist, the photoresist is stripped from the surface of the substrate 110 using a stripper solution (such as a potassium base).

Subsequent to completion of the conductive layer 130 (whether with or without the removal of non-conductive layer), embodiments provide that the substrate and/or conductive layer may be subjected to post-processing steps, such as, for example, polishing or roughening. Numerous such post-process steps may be performed under embodiments described herein.

### Via Formation

Embodiments described herein may provide for the formation of vias that extend conductivity between surfaces of the device or component being plated. In general, vias are provided as conductive apertures that extend into the thickness of a substrate, so as to extend from a first conductive plane or surface to another conductive plane or surface.

With regard to an embodiment of FIG. 1A-FIG. 1G, a via 140 may be plated as a current carrying element that intersects the substrate. In one embodiment, a hole 142 for a via may be drilled or otherwise formed in the substrate 110, so as to extend through the conductive layer 108 and the layer of VSD material 112 (See FIG. 1C). In step of FIG. 1D, the application of voltage VS may be applied to the entire layer of VSD material 112, including thicknesses that have the hole 142. In step of FIG. 1E, light is directed through the hole 142 during the electrolytic process, in order to switch portions of the VSD material 112 that form the walls of the via into the conductive state. When immersed in, for example, the electrolytic solution, conductive elements may bond to the walls of the hole 142 and provide a continuous path within the hole to form the via 140 (see FIG. 1F and FIG. 1G).

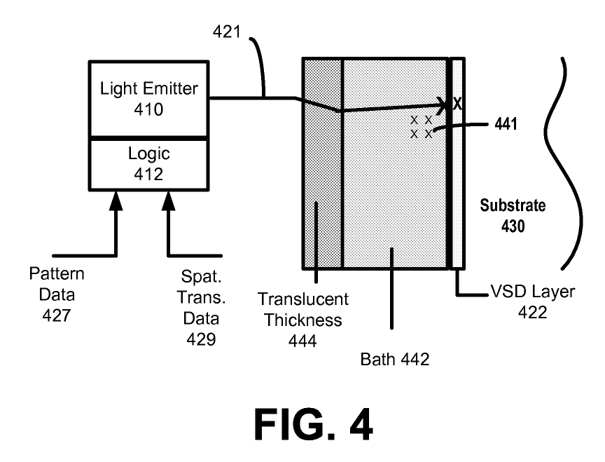

Other techniques are also contemplated for forming vias using the combination of VSD material and light. In one embodiment, a technique such as described with an embodiment of FIG. 4 may be employed to form the via 140 of FIG. 1G and FIG. 1H.

Reduced Threshold Voltage Level Using Light

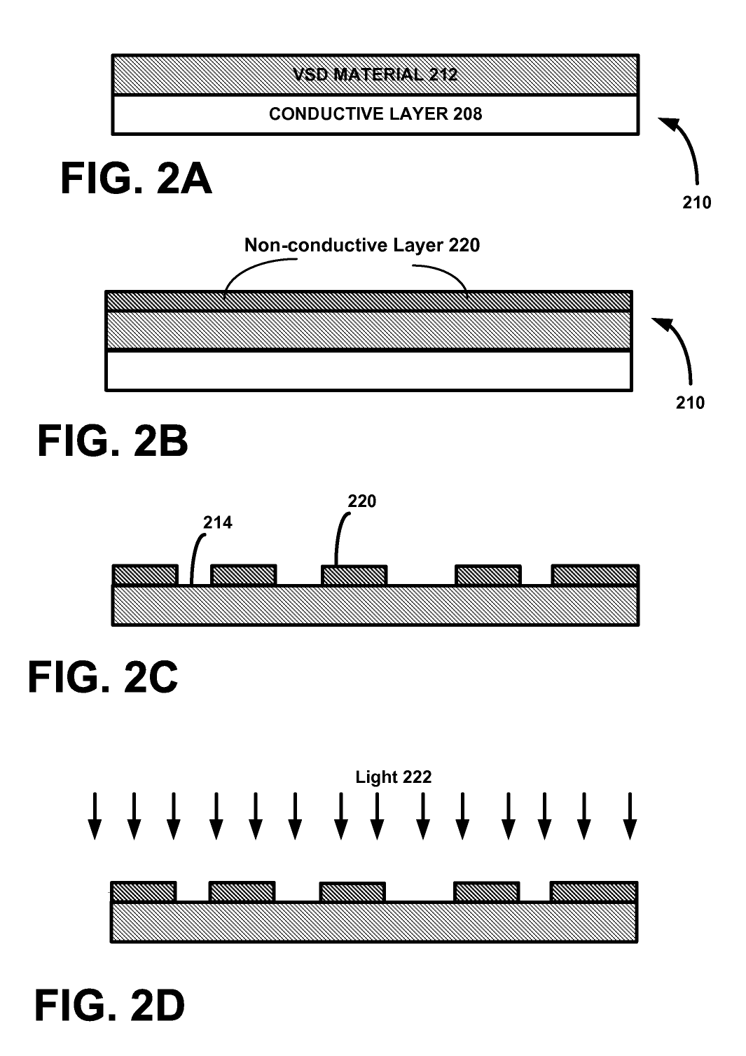

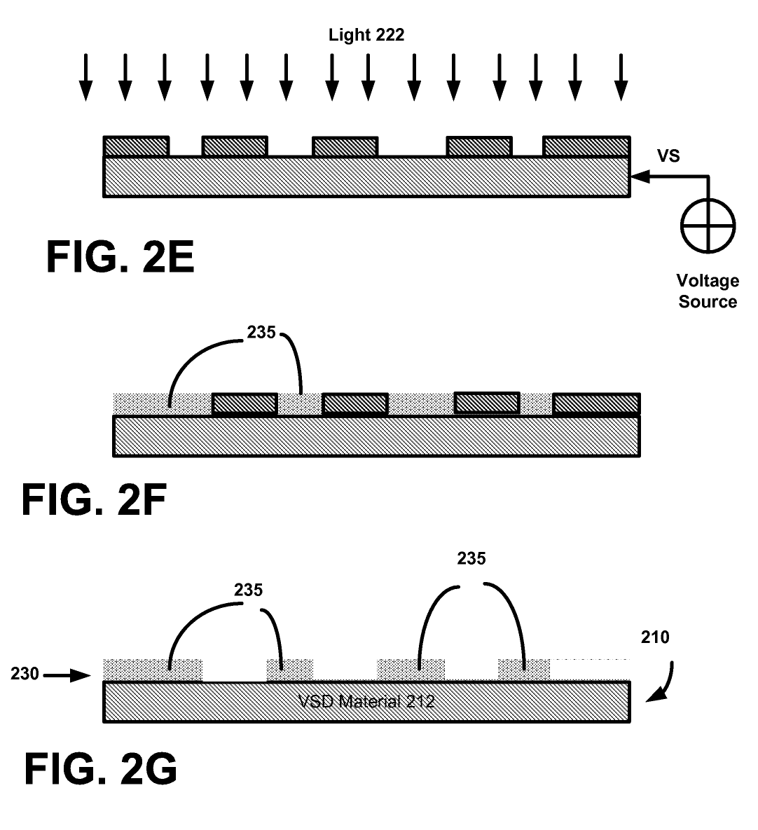

FIG. 2A-FIG. 2G illustrate a variation to the electroplating process described with an embodiment of FIG. 1A-FIG. 1G, under another embodiment of the invention. In particular, an embodiment of FIG. 2A-FIG. 2G provides for the use of light to reduce an overall threshold voltage that is otherwise required to switch select surface regions of the VSD material.

As with prior embodiments, an embodiment provides that in a step of FIG. 2A, photoactive VSD material 212 is selected for use as part of a substrate 210. The photoactive VSD material may be selected based on characteristics that include its known threshold voltage level when applied or otherwise used in a particular electroplating application. IStill further, other electrical properties (e.g. off-state resistance) may also be considered for a given electroplating or metal deposition process. The threshold voltage level may determine the level of the voltage VS that can be applied to the thickness of the VSD material without switching the entire thickness in the conductive state. The substrate 210 may also include a conductive layer 208. Other embodiments may omit the conductive layer 208, or provide for it to be non-conductive (such as a backing).

In FIG. 2B, a non-conductive layer 220 is formed over the combined substrate 210. Then in FIG. 2C, the non-conductive layer is patterned using, for example, a mask that exposes surface regions of the VSD material 212 on the substrate 110. The resulting exposed pattern corresponds to areas where conductive elements are to be deposited.

In FIG. 2D, light 222 is directed or cast onto the combined substrate, including the exposed portions of the VSD material. The light 222 may be provided by, for example, a high-energy lamp or laser. The light 222 generates an incremental amount of energy that affects given regions of the surface thickness of the layer of VSD material 212.

In FIG. 2E and 2F, a voltage VS is applied from another source while the combined substrate 210 is subjected to an electrolytic process (e.g. combined substrate 210 is immersed in electrolytic bath). In general, the duration of applied voltage VS is short (e.g. less than a second), and as such, the steps shown by FIG. 2E and FIG. 2F may be performed nearly simultaneously. Given a threshold voltage level needed to switch the entire thickness of VSD material 212 on, the applied voltage VS may be assumed to be less than the threshold voltage VT. But for a given measurement (i) of the surface thickness of the layer of VSD material that receives the light 222, the threshold voltage level (VTi) is exceeded. This means that with application of VS, select surface regions of the layer of VSD material 212switch into the conductive state. In this way, the use of the light to provide VL acts as a precursor that enables reduction of the applied voltage VS that would otherwise be needed to exceed the threshold voltage level VT at specific surface regions of the VSD material 212.

In an embodiment, the layer of VSD material 212 is only used to create a seed layer for conductive elements 235. Once electrical elements bond to the VSD material in the conductive state, the bonded electrical elements provide the contact surface for subsequent elements in the electrolytic medium. As such, the need to maintain the VSD material 212 in the conductive state may diminish or be eliminated once the seed layer forms.

In FIG. 2G the non-conductive layer 220 is removed as necessary from the substrate. In an embodiment in which the non-conductive layer 220 is the photoresist, the photoresist is stripped from the surface of the substrate 110 using a base solution, such as a potassium base (KOH). Still, other embodiments may employ water to strip the resist layer.

As a completing step, one or more embodiments provide that the resulting conductive layer 230 and/or substrate 210 are further subjected to additional treatment steps, such as polishing or roughening. Numerous treatments are possible.

As described with previous embodiments, one or more vias (not shown in FIG. 2A-FIG. 2G) may be formed as holes that extend through the combined substrate and VSD material. In an embodiment such as described above, light may be directed into holes of the substrate 210 while the electrolytic process is being performed in order to plate the interior of surface walls of the holes that are to form the vias. In another embodiment, lasers may be used in connection with performance of the plating process, in a manner described with an embodiment of FIG. 4.

Among other benefits, the use of light can measurably reduce the amount of applied voltage VS needed to switch the VSD material on. For example, the use of light 222 in combination with photoactive VSD material enables a reduction of the applied voltage VS needed to switch the VSD material on by an amount of 10-50%.

Still further, embodiments such as described with FIG. 1A-FIG. 1G and FIG. 2A-2G offer several benefits, including easing the use of VSD material in a plating process for substrate devices, and simplifying steps for deposition of the seed layer in an electroplating process.

Embodiments such as shown and described above provide for use of a non-conductive layer to pattern the conductive layer over the VSD layer. As a non-conductive layer is used to define the shape and location of conductive elements on the substrate, embodiments described above can apply light voltage indiscriminately to the VSD layer in order to switch the layer on.

Using Light to Form Seed Layer Pattern on Layer of VSD Material

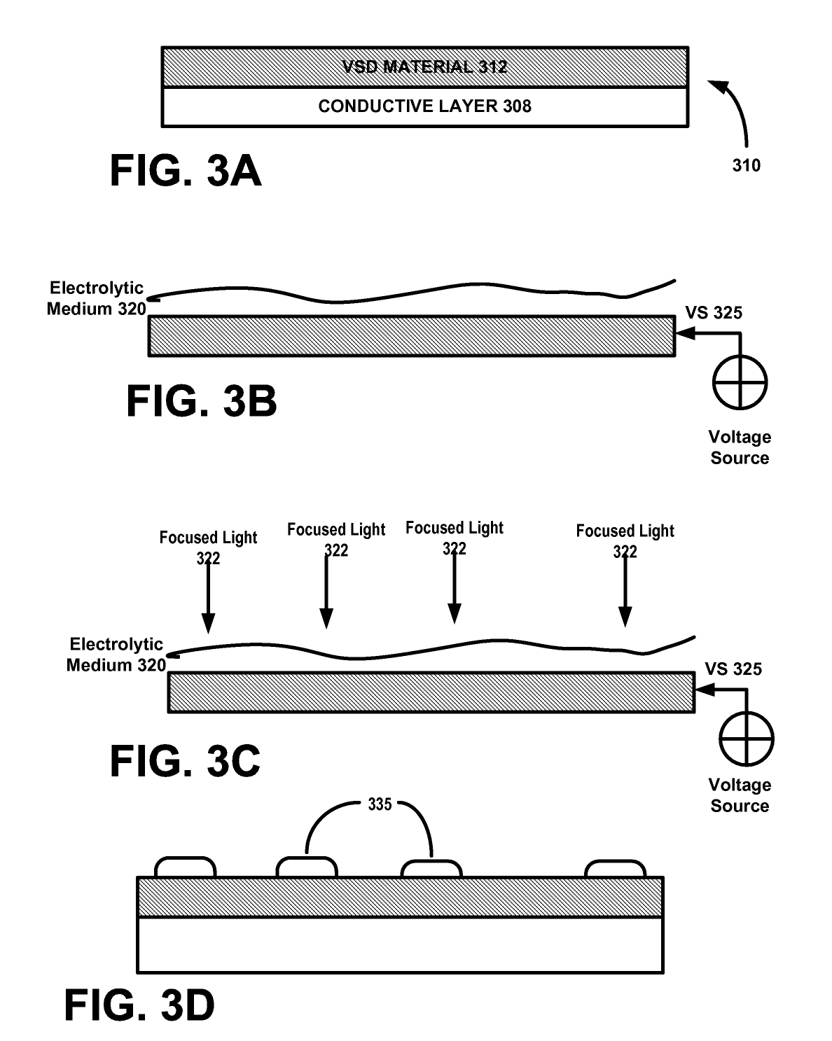

As an alternative, an embodiment in FIG. 3A-FIG. 3D which provides for use of highly-focused light (such as provided with lasers) that is directed onto select portions of a VSD layer in accordance with a pre-determined pattern, in order to form a corresponding pattern of conductive elements on the VSD layer. The resulting pattern of conductive elements provide a seed layer for subsequent plating and formation of current-carrying elements. The use of lasers (or highly focused light) a manner such as described below enables the light to form the patterned seed layer on, for example, a substrate device (such as a printed circuit board). Thus, the laser can substitute for application and masking of a non-conductive layer.

In order to reduce energy requirements required for the source of the focused light, one or more embodiments may incorporate the following considerations: (i) the VSD material may be composed or configured to require low threshold voltage levels to switch on; and (ii) the VSD material may be configured to maximize photoactivity. Furthermore, the threshold voltage level VT needed to switch the entire thickness of VSD material on may be precisely known, so that the applied voltage VS is provided to be sufficiently proximate to VT to enable pulsed light to provide sufficient energy to the desired select surface regions of the VSD material.

With the considerations in mind, the VSD material 312 may be selected and/or formulated in a step of FIG. 3A as part of a substrate 310. The VSD material 312 may be provided over a conductive layer 308, such as a plate, mesh or grid. Alternatively, the VSD material 312 may be provided as the entire substrate, or the conductive layer 308 may be substituted for a non-conductive layer.

In step of FIG. 3B, the substrate 310 is exposed to an electrolytic medium 320 while being applied a voltage 325 from an external source. The application of voltage 325 may be less than the threshold level VT needed to switch the entire thickness of VSD material 312 into the conductive state, so that in and of itself, the applied voltage 325 does not switch any portion or region of the VSD material on.

Concurrently or subsequently to a step of FIG. 3C, focused light 322 is directed selectively, and in accordance with a pre-determined pattern, onto the layer of VSD material. The pre-determined pattern used to apply the focused light 322 may be based on a desired pattern for a seed layer of conductive elements. The addition of focused light 322 to select regions of the layer of VSD material is sufficient to switch those select regions on, while maintaining non-select regions of the VSD material in the off-state. More specifically, at the spots where the focused light 322 is received, the VSD material is made conductive, and conductive elements 321 carried in the electrolytic medium 320 are bonded to the regions of the VSD material at those regions.

With regard to performing a step of FIG. 3C, a laser (e.g. helium neon laser) may be directed through an electrolytic solution (and optionally a translucent thickness) and moved or selectively positioned to form the desired pattern. A system such as described with an embodiment of FIG. 4 may be used to position the laser.

A finished or semi-finished substrate device with electrical elements 335 is shown in FIG. 3D. Subsequent to formation, numerous possible steps such as polishing or roughening of the conductive layer may be formed.

FIG. 4 illustrates a system for implementing the application of focused light onto a layer of VSD material, for purpose of enabling the formation of a pattern of current-carrying elements to be formed thereon during an electrolytic (or metal deposition) process, under an embodiment of the invention. A system 400 may include a focused-light emitter 410, such as a laser, coupled or combined with logic 412. The logic 412 may be provided with firmware, software, or hardware, either integrated with the light-emitter 410 or provided separately and coupled. The light-emitter 410 may include machinery or components to enable movement of a head or other component that determines the position of the generated light beam.

According to an embodiment, VSD material 422 may be provided as a surface thickness of a substrate 430. Some or all of the substrate 430 may be provided in an electrolytic medium. The electrolytic medium 440 may include a bath 442 containing conductive particles 441 that are to be deposited onto the surface of the VSD material 422. In one implementation, the substrate 430 may be immersed in bath 442 so that VSD material 422 is facing the surface of the bath. In another implementation, the substrate 430 may be positioned within the bath 442 so that a translucent thickness 444 (e.g. such as glass) may face the layer of VSD material 422.

The light emitter 410 may, under the control of logic 412, direct light in a pattern that is controlled by logic 412. Initially, focused light 421 emitted from light emitter 410 may make contact with a region of the layer of VSD material 422 that includes the position X. From the initial position X, the focused light 421 may be moved in any direction along the plane or surface defined by the layer of VSD material 422, in accordance with a desired pattern. Alternatively, the focused light 421 may be pulsed at discrete locations that collectively form the paths or routes defined by the pattern.

In controlling the light emitter 410, the logic 412 may use pattern data 427 that defines the desired pattern of conductive elements on the substrate 430, as well as spatial transformation data 429. The spatial transformation data 429 maps individual positions of emissions of the light emitter 410 to corresponding coordinates on the surface of the substrate 430. In mapping the emission positions to the coordinate/position of the substrate 430, the logic 412 takes into account factors that include the amount of bending or diffraction that occurs as a result of the focused light passing through the medium of the bath 442, and optionally the translucent thickness 444 (depending on the orientation of the substrate).

An embodiment such as described with FIG. 3A-FIG. 3D may be used to form some or all of a conductive seed layer for use on a surface undergoing an electroplating or metal deposition process. For example, in one embodiment, a printed circuit board may have various traces of conductive elements formed through a process such as described above. Subsequent to the formation, the electrolytic process may continue (or be completed separately) to form conductive paths and components from the traces formed.

Technique for Via Formation

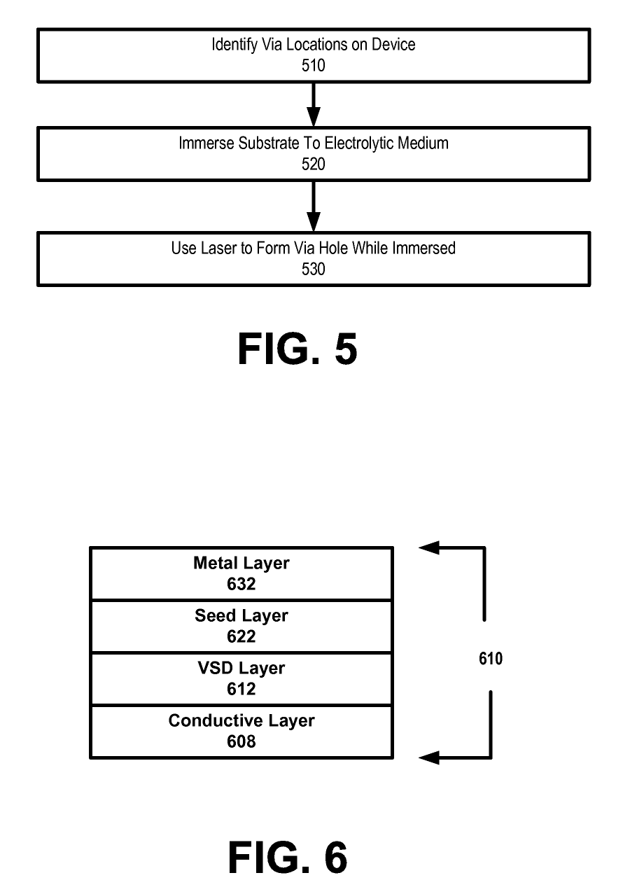

With regard to any of the embodiments described herein, the formation of one or more vias (e.g. via 140 of FIG. 1F) may also be accomplished through use of light. In particular, an embodiment of FIG. 5 illustrates the use of light and VSD material of a substrate undergoing an electrolytic process in order to form one or more conductive vias, according to an embodiment of the invention. Reference is made to an embodiment of FIG. 1A-FIG. 1G for purpose of illustrating suitable elements for performing a step or sub-step.

In step 510, locations for individual vias are identified on the substrate 110 comprising the layer of VSD material formed over the conductive thickness 108. The locations may be identified based on, for example, desired locations for providing grounding features or interconnectivity between conductive planes of the substrate (e.g. top surface and bottom surface).

In step 520, the substrate 110 is immersed or otherwise subjected to an electrolytic medium, such as provided as part of an electrolytic process described with FIG. 1D (application of voltage) and FIG. 1E (application of light).

Step 530 provides that a laser (emitting a laser beam) is used to bore holes in locations identified in step 510 while the substrate 110 is immersed or provided in the electrolytic medium. The performance of step 530, including the use of the laser, may be additive to, for example, the use of light 122 to form conductive elements on the surface of the substrate 110. Thus, for example, in one implementation, the voltage VS is applied to the layer of VSD material 112, and a high-energy lamp is used to plate the surface of the substrate 110. While the substrate 110 is immersed and the voltage VS is applied, the one or more laser beams may be applied to the identified locations, causing both the formation of the holes and the bonding of conductive elements deposited from the electrolytic solution.

Still further, embodiments recognize that a sufficiently powered laser beam may provide the necessary level of energy to switch a surface thickness (extending into the layer of VSD material 112) of the layer of VSD material that provides the walls defining vias 140 into the conductive state, without application of the voltage VS. Specifically, the act of boring the hole into the substrate 110 may result in the VSD material 112 that surrounds the hole (extending depth-wise into the layer of VSD material) in being conductive (at least while the laser beam is present on the surface). Thus, as an alternative, the holes may be bored with a high-powered laser beam while the substrate is immersed in the electrolytic medium, but before or after the application of the voltage VS (if that voltage is even applied).

An example of a laser that may be used with an embodiment of FIG. 5 includes a helium neon laser. Under one embodiment, a method for forming a via such as described with FIG. 5 may be implemented using equipment such as described with an embodiment of FIG. 4, including the light-emitter 410 and logic for locating positions where the vias are to be provided.

While an embodiment such as described provides for the emitted laser to pass through the substrate, one or more embodiments also provide that the hole may at least partially pre-formed, either depth wise or radially, before application of the laser or light beam.

Additional Applications

Embodiments recognize that the use of VSD material in a plating or metal deposition process may be most useful when plating a seed layer onto the substrate undergoing the plating or metal deposition process. Specifically, once an initial coat of conductive elements is formed on a region of VSD material, subsequent conductive elements coat each other, rather than the VSD material.

FIG. 6 illustrates a section of a substrate that undergoes multiple electroplating or metal deposition processes, including an initial process that uses an underlying layer of VSD material, under an embodiment of the invention. In particular, a portion of a substrate 610 includes a conductive layer 608, a layer of VSD material 612, a seed layer 622, and one or more metal layers 632. The seed layer 622 may be formed in accordance with any of the embodiments described herein. Once the seed layer 622 is formed, the same or subsequent process may be used to form the additional metal layers 632. In one embodiment, the additional metal layers are formed in other processes, thus enabling a non-homogenous layer of conductive elements.

In one embodiment, for example, a pre-formed substrate or thickness may be manufactured to include VSD material for use in electroplating processes. The pre-formed substrate may be used in a process such as described with embodiments of FIG. 1A-FIG. 1G, FIG. 2A-FIG. 2G or FIG. 3A-FIG. 3D (or elsewhere in this application) in order to create the seed layer through an electroplating process (as described). The conductive elements may be formed through either subsequent continuous electroplating, or as shown by an embodiment of FIG. 6, through additional and subsequent electroplating steps.

Control System

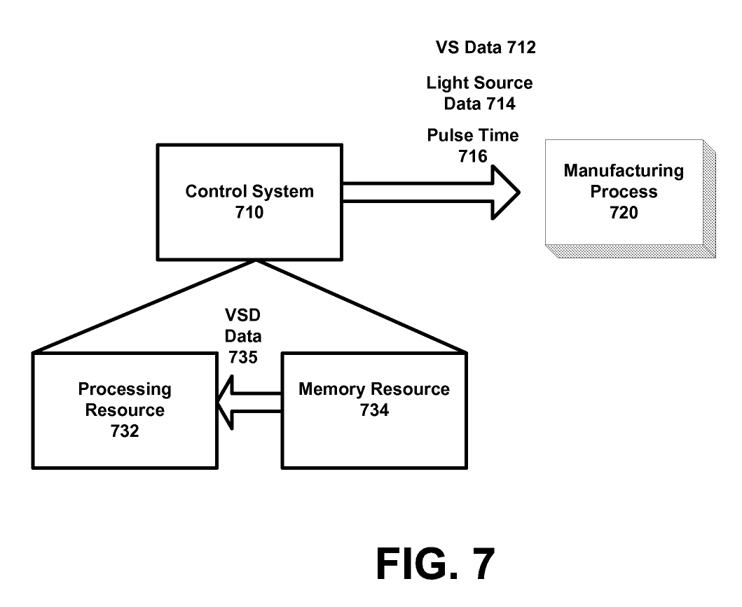

FIG. 7 illustrates a control system for use with one or more embodiments described herein. In particular, embodiments such as described herein may be implemented through the a system comprising a combination of manufacturing/fabrication tools and machines that perform the physical tasks of applying the various tasks through various manufacturing steps. Such a system of tools and machines may be controlled by a control computer.

In an embodiment depicted by FIG. 7, a control system 710 controls a manufacturing process 720. The manufacturing process 720 includes the use of tools and materials (including VSD material and material for non-conductive layers) for performing any of the steps shown with embodiments of FIG. 1A-FIG. 1G, FIG. 2A-FIG. 2G, or FIG. 3A-FIG. 3D. In an embodiment, the control system 710 provides the manufacturing process 720 with different kinds of data to control or configure one or more steps, or portions thereof, for fabricating or manufacturing a substrate device. In one embodiment, the control system 710 sends data corresponding to necessary voltage levels of the applied voltage VS (VS data 712), data to control timing and duration of the light source (“light source data 714”), data to control the brightness or energy level of the light source (“pulse time 716”) and data that identifies the pattern of any one or more of the non-conductive layer, the conductive pattern, and/or the pattern in which light is cast or directed onto the substrate during formation (consistent with embodiments of FIG. 3A-FIG. 3D). In other embodiments, the control system 710 may send other forms of data to the manufacturing process 720. For example, with respect to an embodiment of FIG. 3A-FIG. 3D, the data may identify the desired seed layer pattern that is to be formed with the application of light.

As mentioned elsewhere in this application, one or more embodiments provide for selection of VSD material for use with the fabrication process. The selection of the VSD material may include identification of the threshold voltage level VT needed to switch the layer of VSD material on in any one of many environments, such as in the environment of a bath for an electrolytic process. The control system 710 may select the VSD material from any one of many criteria, including the threshold voltage level that is needed, and potentially the tolerance levels of the components that may subsequently use or be affected by the layer of VSD material when the substrate manufacturing is complete.

In making the selection of VSD material, the control system 710 may include processing resources 732 that communicate with memory resources 734 to extract and process VSD material information 735. The VSD material information 735 may include data that identifies VSD material by type or composition, as well as properties such as the materials characteristic voltage level and leakage/off-state resistance. It will be appreciated that numerous types of VSD material may exist, with different concentration levels of a particular type of VSD material, as well as different kinds of photo-receptive particles (such as different kinds of fullerenes). The memory resources 734 may maintain the information and enable the processing resources 732 to determine different data that may affect the manner in which the VSD material is to be used by the fabrication process 720. This may include, for example, selecting or designating a thickness of the VSD material (or alternatively determining the threshold voltage level VT), determining whether more than one type of VSD material to be used, identifying locations for layers of VSD material before plating is initiated, determining the voltages for VS and/or the amount of energy that is to be provided with light, as well as other information such as the pulse length for the time in which the applied voltage VS and/or the combination of VS and light are to be applied.

With regard to instructions, data and internal operations of the control system 710, one or more embodiments provide that any of the data, instructions etc. may be stored on any form of computer-readable medium. Examples of computer-readable mediums include permanent memory storage devices, such as hard drives on personal computers or servers. Other examples of computer storage mediums include portable storage device such as CD or DVD, flash memory (such as carried on many cell phones and personal digital assistants (PDAs)), and magnetic memory. Computers, terminals, network enabled devices (e.g. mobile devices such as cell phones) are all examples of machines and devices that utilize processors, memory, and instructions stored on computer-readable mediums.

Alternative Embodiments

While numerous embodiments provided herein describe the use of VSD material applied to a conductive layer (e.g. plate, mesh or grid) to form a substrate, one or more embodiments further provide that a layer of VSD material may be formed and used in accordance with any of the embodiments described herein, without need of a conductive layer. In one embodiment, the substrate (e.g. substrate 110 of FIG. 1A) may comprise only a single layer of VSD material. The single layer of VSD material may undergo processes such as described to enable formation of conductive elements thereon. The layer of VSD material may include a composition that is sufficiently rigid or durable to enable its affixation to a desired environment. In another embodiment, the substrate may comprise the layer of VSD material affixed to a backing layer that is non-conductive, so as to provide mechanical integrity to the layer of VSD material.

With regard to any of the embodiments described herein, one or more embodiments provide for the additional step of heat treatment of the substrate or thickness that includes the VSD material. The heat treatment may improve the properties of one or more of the deposited metals and/or the VSD material, including the electrical properties. Heating may also facilitate drying the thickness, improving adhesion of the different layers that result from plating, reducing stress from the plating process, and annealing metal traces formed from plating. The amount of heating may be significant, but should not exceed an amount that results in degradation of the VSD material.

Conclusion

Although illustrative embodiments of the invention have been described in detail herein with reference to the accompanying drawings, it is to be understood that the invention is not limited to those precise embodiments. As such, many modifications and variations will be apparent to practitioners skilled in this art. Accordingly, it is intended that the scope of the invention be defined by the following claims and their equivalents. Furthermore, it is contemplated that a particular feature described either individually or as part of an embodiment can be combined with other individually described features, or parts of other embodiments, even if the other features and embodiments make no mentioned of the particular feature. Thus, the absence of describing combinations should not preclude the inventor from claiming rights to such combinations.

What is claimed is:

1. A method for electroplating, the method comprising:
on a thickness that includes photoactive voltage switchable dielectric (VSD) material, forming a pattern of conductive elements by switching at least a portion of the VSD material from a dielectric state to a conductive state using, in part, energy generated by directing light onto the thickness having the portion of the VSD material.

2. The method of claim 1, wherein forming a pattern of conductive elements by at least a portion of the VSD material includes switching at least a portion of a surface thickness of the VSD material into the conductive state, and subjecting the thickness that includes the VSD material to an electrolytic medium.

3. The method of claim 2, wherein switching at least the portion of the surface thickness includes switching select portions of the surface thickness so as to at least partially define a seed layer that is to be formed on the thickness.

4. The method of claim 1, wherein switching select portions that define the seed layer include switching the select portions to conform to the pattern of conductive elements that are to be subsequently formed.

5. The method of claim 1, wherein forming the pattern of conductive elements includes (i) forming a layer of non-conductive material over the VSD material, and (ii) forming the pattern by removing portions of the non-conductive layer to expose the VSD material.

6. The method of claim 5, wherein forming the pattern of conductive elements includes subjecting the substrate comprising the VSD material to an electrolytic process.

7. The method of claim 1, further comprising forming the substrate to include VSD material comprising one or more of (i) fullerenes, (ii) titanium dioxide, (iii) zinc oxide, or (iv) cerium dioxide.

8. The method of claim 3, wherein forming the pattern of conductive elements includes applying a voltage from another voltage source to the substrate, the voltage from the voltage source being less than a threshold voltage level needed to switch the VSD material into the conductive state, and then directing the light onto a surface of the VSD material during the electrolytic process.

9. The method of claim 8, wherein directing the light onto the surface of the VSD material includes pulsing the light for a controlled duration using a high-energy beam, wherein energy resulting from pulsing the light combines with voltage from the other source to cause_the VSD material to switch into the conductive state.

10. The method of claim 6, wherein forming the pattern of conductive elements includes (i) directing light onto the substrate to generate a voltage across the layer of VSD material, and then while the voltage generated from light is present, (ii) applying a voltage from a voltage source during the electrolytic process, wherein the voltage from voltage source is less than a threshold voltage level needed to switch the VSD material into the conductive state except when combined with light that is present across the surface of the VSD material to switch a surface thickness of the VSD material into the conductive state.

11. The method of claim 1, further comprising heating the thickness after forming the pattern of conductive elements.

12. A substrate device formed by a process that comprises steps of:
providing a substrate that includes voltage switchable dielectric (VSD) material formed with photoactive components;
forming a pattern of conductive elements by switching at least a portion of the VSD material from a dielectric state to a conductive state using, in part, voltage generated by casting light onto the substrate.

13. A method for electroplating, the method comprising:
subjecting a thickness comprising a layer of voltage switchable dielectric (VSD) material to a medium containing conductive particles, the layer of VSD material including photoactive components and being triggerable to switch from a dielectric state into a conductive state with application of energy that exceeds a designated threshold level; and
directing focused light onto the layer of VSD material in accordance with a designated pattern, the focused light causing select portions of the VSD material that are identified in the designated pattern to trigger into the conductive state, so that conductive particles in the medium bond to the VSD material in accordance with the designated pattern.

14. The method of claim 13, wherein directing focused light includes directing a laser onto the surface of the VSD material.

15. The method of claim 13, wherein directing focused light includes controlling a light emitter to position a beam of focused light to intersect the layer of VSD material at a desired position.

16. The method of claim 15, wherein controlling the light emitter includes factoring in bending or diffraction of the beam as a result of the beam passing through the medium in intersecting the layer of VSD material at the desired position.

17. The method of claim 13, wherein further comprising forming the VSD material of the thickness to include particles selected from a group consisting of (i) fullerenes, (ii) titanium dioxide, (iii) zinc oxide, and (iv) cerium oxide.

18. A system for electroplating a substrate provided in a medium of conductive particles, the system comprising:
a light emitter that directs a beam of focused light;
logic coupled to or provided with the light emitter that is configured to control a position where the beam is provided, wherein the logic is configured to position the beam generated from the light emitter on a layer of a VSD material provided on the substrate using pattern data that defines a desired pattern of a conductive layer that is to be formed on the substrate;
wherein the VSD material includes photoactive components and is triggerable to switch from a dielectric state into a conductive state with application of energy that exceeds a designated threshold level;
wherein light emitter is configured to direct the beam to provide sufficient energy to select surface regions of the layer of VSD material so as to exceed the designated threshold of energy of the VSD material at those select regions, and so as to cause the VSD material at the select regions to switch from the dielectric state into the conductive state.

19. The system of claim 18, wherein the logic is further configured to use spatial transformation data to position the beam generated from the light emitter, the spatial transformation data including one or more parameters that account for a diffraction or bending of the light beam passing through the medium of conductive particles.

20. The system of claim 18, wherein the light-emitter is a laser.

21. A control system for controlling a manufacturing process for a substrate device, the control system comprising:
one or more processing resources that communicate data to the manufacturing process, the data including instructions or parameters to direct the manufacturing process to perform steps comprising:
providing a substrate that includes voltage switchable dielectric (VSD) material formed with photoactive components;
forming a pattern of conductive elements by switching the VSD material from a dielectric state to a conductive state using, in part, voltage generated by directing light on the substrate and VSD material.

22. A method for forming a via in a substrate, the method comprising:
forming a layer of VSD material on the substrate, the VSD material including photoactive components being triggerable to switch from a dielectric state into a conductive state with application of energy that exceeds a designated threshold level;
immersing at least a portion of the substrate, including the layer of VSD material, to a medium comprising conductive particles; and
while at least the portion of the substrate is immersed, applying light to the substrate so as to pass through a hole in the substrate, wherein the light provides sufficient energy to a portion of the VSD material that define the hole, so as to cause an energy level of that portion of the VSD material to exceed the designated threshold and switch into the conductive state;
wherein in the conductive state, the conductive particles from the medium bind to the portion of the VSD material that defines the hole, so as to form the via.

23. The method of claim 22, wherein applying light to the substrate so as to pass through one or more holes includes applying a laser beam to the substrate for form the one or more holes.

24. A substrate device having a via formed by a process that comprises steps of:
forming a layer of VSD material on the substrate, the VSD material including photoactive components and being triggerable to switch from a dielectric state into a conductive state with application of energy that exceeds a designated threshold level;
immersing at least a portion of the substrate, including the layer of VSD material, to a medium comprising conductive particles; and
while at least the portion of the substrate is immersed, applying light to the substrate so as to pass through a hole in the substrate, wherein the light provides sufficient energy to a portion of the VSD material that define the hole, so as to cause an energy level of that portion of the VSD material to exceed the designated threshold and switch into the conductive state;
wherein in the conductive state, the conductive particles from the medium bind to the portion of the VSD material that defines the hole, so as to form the via.

25. A system for forming a via in a substrate, the system comprising
a light emitter that is configurable to direct a beam of focused light onto the substrate;
logic coupled to or provided with the light emitter that is configured to control a position where the beam is provided, wherein the logic is configured to position the beam generated from the light emitter on a layer of a VSD material provided on the substrate at a position corresponding to a desired location for a via;
wherein the VSD material includes photoactive components and is triggerable to switch from a dielectric state into a conductive state with application of energy that exceeds a designated threshold level; and
wherein light emitter is configured to direct the beam to provide sufficient energy to portions of the layer of VSD material that form, or are to form, a hole for the via, so that the VSD material at those portions exceeds the designated threshold of energy and switches from the dielectric state into the conductive state.
